(19) United States
(12) Patent Application Publication
(10) Pub. No.: US 2026/0353601 A1
(43) Pub. Date: Nov. 5, 2026

(54) IMMERSION-COOLING DEVICE

(71) Applicant: MITSUBISHI HEAVY INDUSTRIES, LTD., Tokyo (JP)

(72) Inventors: Nobuhide Hara, Tokyo (JP); Sumiu Uchida, Tokyo (JP); Hiroko Kitamoto, Tokyo (JP)

(73) Assignee: MITSUBISHI HEAVY INDUSTRIES, LTD., Tokyo (JP)

(21) Appl. No.: 18/997,198

(22) PCT Filed: Feb. 9, 2023
(86) PCT No.: PCT/JP2023/004297

§ 371 Date: Jan. 21, 2025

(30) Foreign Application Priority Data
Jul. 22, 2022 (JP) 2022-117545

(51) Int. Cl. H05K 7/20

(52) U.S. Cl. CPC H05K 7/20272; H05K 7/20236; H05K 7/20772

(57) ABSTRACT

An immersion-cooling device includes: a casing group including a plurality of casings, which form a box shape extending in a horizontal direction and in which a board is disposed to extend in the horizontal direction, the casing group being configured by arranging the plurality of casings in an up-down direction; a supply-side header extending in the up-down direction to be adjacent to the casings and configured to introduce a first refrigerant into each of the plurality of casings; a discharge-side header extending in the up-down direction to be adjacent to the casings and configured to receive introduction of the first refrigerant from each of the plurality of casings; a refrigerant pumping unit configured to pump the first refrigerant from the discharge-side header to the supply-side header; and a heat transfer pipe extending inside at least one of the discharge-side header and the supply-side header.

### TECHNICAL FIELD

The present disclosure relates to an immersion-cooling device.

Priority is claimed on Japanese Patent Application No. 2022-117545, filed Jul. 22, 2022, the content of which is incorporated herein by reference.

### BACKGROUND ART

Patent Document 1 discloses a cooling system that cools an electronic device including a heating element. The cooling system includes a cooling tank containing a refrigerant. The electronic device is immersed in the refrigerant of the cooling tank.

The electronic device is disposed in the cooling tank in a plurality of vertical positions. The refrigerant in the cooling tank circulates such that the refrigerant is cooled outside the cooling tank after cooling the heating element and then supplied to the cooling tank again.

### CITATION LIST

### Patent Document

Patent Document 1: PCT International Publication No. WO2016/075838

### SUMMARY OF INVENTION

### Technical Problem

However, in the cooling system described in Patent Document 1, a plurality of electronic devices are disposed in a vertical posture in one cooling tank, which results in a large cooling system.

In addition, since it is required to fill a large cooling tank with a refrigerant, a use amount of the refrigerant is large. Further, equipment for cooling the refrigerant in the cooling tank is required separately. Therefore, a lot of time and cost are required for managing the refrigerant, and thus it is difficult to manage the refrigerant.

The present disclosure has been made in order to achieve the above-described object, and an object of the present disclosure is to provide an immersion-cooling device that can improve manageability of a refrigerant while achieving reduction in size.

### Solution to Problem

In order to achieve the above-described object, the present disclosure provides an immersion-cooling device that cools a heating element provided on a board, the immersion-cooling device including: a casing group including a plurality of casings, which form a box shape extending in a horizontal direction and in which the board is disposed to extend in the horizontal direction, the casing group being configured by arranging the plurality of casings in an up-down direction; a supply-side header extending in the up-down direction to be adjacent to the casings and configured to introduce a first refrigerant into each of the plurality of casings; a discharge-side header extending in the up-down direction to be adjacent to the casings and configured to receive introduction of the first refrigerant from each of the plurality of casings; a refrigerant pumping unit configured to pump the first refrigerant from the discharge-side header to the supply-side header; and a heat transfer pipe extending inside at least one of the discharge-side header and the supply-side header and configured to cool the first refrigerant by exchanging heat between a second refrigerant flowing through an inner portion of the heat transfer pipe and the first refrigerant.

The present disclosure provides an immersion-cooling device that cools a heating element provided on a board, the immersion-cooling device including: a casing configured to store a first refrigerant and in which the board is disposed to extend in a horizontal direction; a jet flow supply unit configured to supply a jet flow of the first refrigerant to the heating element; and a heat transfer pipe penetrating the casing and configured to cool the first refrigerant by exchanging heat between a second refrigerant flowing through an inner portion of the heat transfer pipe and the first refrigerant.

### Advantageous Effects of Invention

With the immersion-cooling device according to the present disclosure, it is possible to improve the manageability of the refrigerant while achieving the reduction in size.

### BRIEF DESCRIPTION OF DRAWINGS

FIG. 1 An overall view showing the schematic configuration of an immersion-cooling device according to a first embodiment of the present disclosure.

FIG. 2 A schematic view of the immersion-cooling device according to the first embodiment of the present disclosure when viewed obliquely.

FIG. 3 A schematic view of a heat sink mechanism according to the first embodiment of the present disclosure when viewed from a side.

FIG. 4 A cross-sectional view of a heat transfer pipe according to the first embodiment of the present disclosure.

FIG. 5 A schematic view of an immersion-cooling device according to a first modification example of the first embodiment of the present disclosure when viewed from a side.

FIG. 6 A cross-sectional view of a heat transfer pipe according to a second modification example of the first embodiment of the present disclosure.

FIG. 7 An overall view showing the schematic configuration of an immersion-cooling device according to a third modification example of the first embodiment of the present disclosure.

FIG. 8 A schematic view of an immersion-cooling device according to a fourth modification example of the first embodiment of the present disclosure when viewed from a side.

FIG. 9 An overall view showing the schematic configuration of an immersion-cooling device according to a fifth modification example of the first embodiment of the present disclosure.

FIG. 10 A schematic view of the immersion-cooling device according to the fifth modification example of the first embodiment of the present disclosure when viewed obliquely.

FIG. 11 An overall view showing the schematic configuration of an immersion-cooling device according to a sixth modification example of the first embodiment of the present disclosure.

FIG. 12 A schematic view of an immersion-cooling device according to a second embodiment of the present disclosure when viewed from a side.

FIG. 13 A schematic view showing the schematic configuration of an entire immersion-cooling device according to a third embodiment of the present disclosure.

FIG. 14 A schematic view showing the schematic configuration of an inner portion of a casing according to the third embodiment of the present disclosure.

### DESCRIPTION OF EMBODIMENTS

### First Embodiment

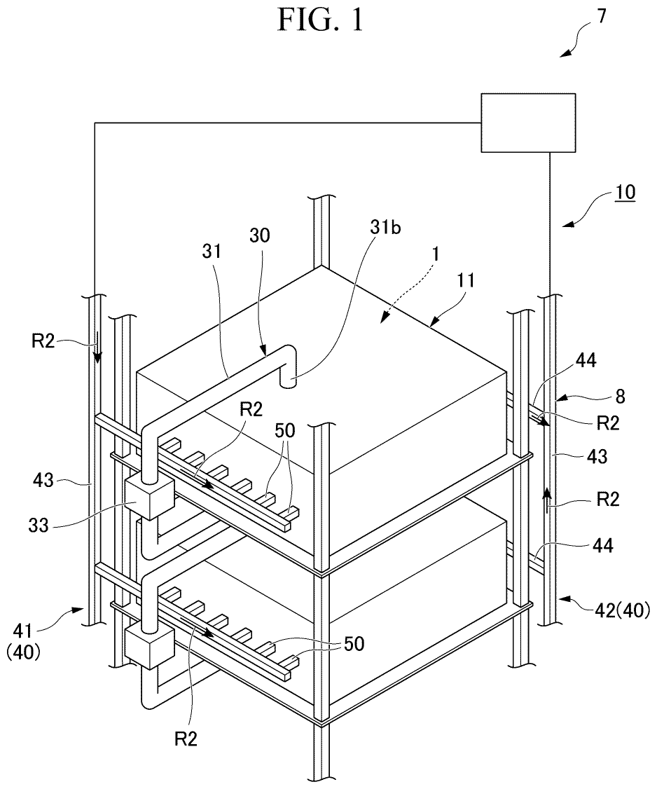

Hereinafter, an immersion-cooling device 10 according to an embodiment of the present disclosure will be described with reference to FIGS. 1 to 4.

As shown in FIG. 1, the immersion-cooling device 10 is used to cool an electronic device that performs high-speed calculation. In the present embodiment, the immersion-cooling device 10 is used for a server 1 installed in a data center. A plurality of the servers 1 are provided. The plurality of servers 1 are installed in each stage of a rack 8 for air cooling. The rack 8 is a general rack formed in a size of, for example, about 19 inches.

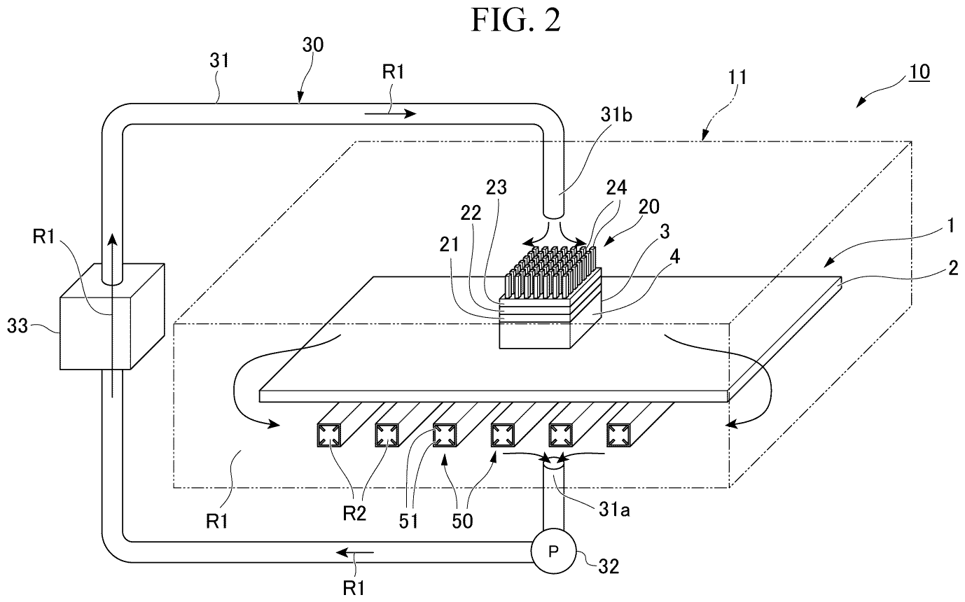

As shown in FIG. 2, the server 1 includes a printed circuit board and an element such as a chip of a CPU or a GPU provided on the printed circuit board. Since the CPU or the GPU is a component responsible for high-speed calculation processing, a high load is applied to the CPU or the GPU, and the CPU or the GPU generates heat at a higher temperature than other portions of the server 1.

A heat exchanger 7 using water as a refrigerant is installed in the data center. Exemplary examples of the heat exchanger 7 include a dry cooler and a chiller. The immersion-cooling device 10 according to the present embodiment is provided separately from the heat exchanger 7 and is used to cool an element that generates heat at a high temperature, such as the CPU or the GPU.

Hereinafter, the printed circuit board of the server 1 may be simply referred to as a “board 2”, and the element that generates heat at a particularly high temperature in the board 2, such as the CPU or the GPU, may be referred to as a “heating element 3”.

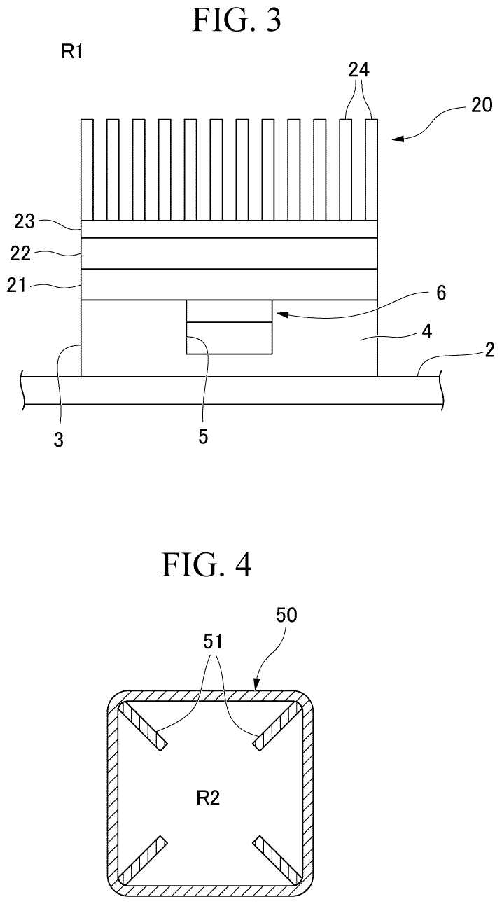

As shown in FIG. 3, the board 2 is formed in a rectangular plate shape. The heating element 3 is provided on a surface of the board 2.

The heating element 3 includes a base portion 4 and a heating element body 6. The base portion 4 is a rectangular plate-shaped member. The base portion 4 is attached to a surface of the board 2. A recess portion 5 is provided on a surface, among the surfaces of the base portion 4, on a side opposite to the board 2. The recess portion 5 is provided at a center portion of the base portion 4. The heating element body 6 is attached to the recess portion 5. The heating element body 6 is a portion that mainly generates heat in the heating element 3. In the present embodiment, the heating element body 6 is a semiconductor constituting the CPU or the GPU. A surface, among the surfaces of the heating element body 6, on a side opposite to the board 2 is flush with the surface of the base portion 4.

### Configuration of Immersion-Cooling Device

Subsequently, a configuration of the immersion-cooling device 10 will be described.

As shown in FIGS. 1 and 2, the immersion-cooling device 10 includes a casing 11, a heat sink mechanism 20, a jet flow supply unit 30, a header pipe 40, and a heat transfer pipe 50.

### Casing

The casing 11 is disposed in each stage of the rack 8. The casing 11 is formed in a rectangular box shape extending in a horizontal direction. A first refrigerant R1 is stored in the casing 11. In the present embodiment, the casing 11 is filled with the first refrigerant R1. That is, an entire storage space in the casing 11 is filled with the first refrigerant R1. The first refrigerant R1 is a refrigerant having insulating properties. The first refrigerant R1 cools the heating element 3 in a liquid-phase state. Therefore, it is desirable that a boiling point of the first refrigerant R1 is 70 degrees or higher. Exemplary examples of the first refrigerant R1 include a fluorocarbon-based liquid.

The board 2 of each server 1 is disposed inside the casing 11 to extend in the horizontal direction. In the present embodiment, the board 2 is disposed such that a surface on a side on which the heating element 3 is provided is upward. The heat sink mechanism 20 is provided on the heating element 3 provided on the board 2.

### Heat Sink Mechanism

The heat sink mechanism 20 is attached to a surface of the heating element 3 on a side opposite to the board 2. As shown in FIG. 3, the heat sink mechanism 20 includes a first heat transfer plate 21, grease 22, a second heat transfer plate 23, and a heat sink fin 24.

### First Heat Transfer Plate

The first heat transfer plate 21 is attached to a surface, among the surfaces of the heating element 3, on a side opposite to the board 2 in a superimposed manner. An outer edge of the first heat transfer plate 21 coincides with an outer edge of the heating element 3 when viewed in an up-down direction. The first heat transfer plate 21 is made of, for example, stainless steel. The first heat transfer plate 21 is provided to increase a surface area of the heating element body 6 and diffuse the heat generation of the heating element body 6.

### Grease

The grease 22 is provided on a surface, among the surfaces of the first heat transfer plate 21, on a side opposite to the heating element 3. The grease 22 bonds the first heat transfer plate 21 and the second heat transfer plate 23 to each other. The first heat transfer plate 21 and the second heat transfer plate 23 are closely attached to each other via the grease 22.

### Second Heat Transfer Plate

The second heat transfer plate 23 is provided on a surface, among the surfaces of the first heat transfer plate 21, on a side opposite to the heating element 3 via the grease 22. The second heat transfer plate 23 is made of, for example, metal such as copper.

### Heat Sink Fin

The heat sink fin 24 is provided on a surface, among the surfaces of the second heat transfer plate 23, on a side opposite to the first heat transfer plate 21. A plurality of the heat sink fins 24 are provided on the second heat transfer plate 23. The heat sink fins 24 are formed in a rod shape to extend perpendicular to the second heat transfer plate 23. The heat sink fins 24 are made of, for example, the same metal, such as copper, as the second heat transfer plate 23. The heat sink fin 24 is provided to further increase the surface area of the heating element body 6 and further diffuse the heat generation of the heating element body 6.

### Jet Flow Supply Unit

As shown in FIG. 2, the jet flow supply unit 30 supplies a jet flow of the first refrigerant R1 to the heating element 3. The jet flow supply unit 30 includes a circulation pipe 31, a pump 32, and a filter 33.

### Circulation Pipe

The circulation pipe 31 is provided outside the casing 11. Both ends of the circulation pipe 31 communicate with the casing 11. The first refrigerant R1 can flow through the circulation pipe 31. In the present embodiment, one end 31a of the circulation pipe 31 is connected to a lower surface of the casing 11. One end 31a of the circulation pipe 31 is provided at a position overlapping the heating element 3 in the up-down direction. The other end 31b of the circulation pipe 31 is connected to an upper surface of the casing 11. The other end 31b of the circulation pipe 31 is provided at a position overlapping the heating element 3 in the up-down direction. Therefore, the other end 31b of the circulation pipe 31 is disposed at a position facing the heating element 3 and the heat sink mechanism 20.

### Pump

The pump 32 is provided in the circulation pipe 31. The pump 32 allows the first refrigerant R1 to flow from one end 31a to the other end 31b of the circulation pipe 31.

### Filter

The filter 33 is provided in the circulation pipe 31. The filter 33 is provided on a downstream side with respect to the pump 32 in a flow direction of the first refrigerant R1. The filter 33 is, for example, an activated carbon filter.

The first refrigerant R1 circulates inside the casing 11 and the circulation pipe 31 via the jet flow supply unit 30. As a result, in the casing 11, the first refrigerant R1 is jetted from the other end 31b of the circulation pipe 31, bypasses the board 2, and flows into one end 31a of the circulation pipe 31.

Hereinafter, in the casing 11, the flow direction of the first refrigerant R1 may be simply referred to as a “flow direction”, the other end 31b side of the circulation pipe 31 in the flow direction of the first refrigerant R1 may be referred to as an “upstream side”, and one end 31a side of the circulation pipe 31 may be referred to as a “downstream side”.

### Header Pipe

As shown in FIG. 1, the header pipe 40 communicates with the heat exchanger 7. The refrigerant of the heat exchanger 7 flows through the header pipe 40.

Hereinafter, the refrigerant of the heat exchanger 7 will be simply referred to as a “second refrigerant R2”.

The header pipe 40 includes a main pipe 43 and a sub-header 44. Each header pipe 40 is provided with one main pipe 43. The main pipe 43 extends in the up-down direction. The sub-header 44 is a pipe in which a plurality of pipes extend from one main pipe 43. All of a plurality of sub-headers 44 extend in the horizontal direction. The plurality of sub-headers 44 extend in parallel to each other, and are disposed at equal intervals in the up-down direction. Two header pipes 40 are provided. In the present embodiment, the two header pipes 40 are provided on sides opposite to each other with the casing 11 interposed therebetween. The second refrigerant R2 is supplied from the heat exchanger 7 to one header pipe 40. The second refrigerant R2 supplied to one header pipe 40 passes through the casing 11 and then is returned to the other header pipe 40. The other header pipe 40 returns the second refrigerant R2, which has passed through the casing 11, to the heat exchanger 7.

Hereinafter, one header pipe 40 to which the second refrigerant R2 is supplied from the heat exchanger 7 will be referred to as a “supply header pipe 41”, and the other header pipe 40 to which the second refrigerant R2 is returned to the heat exchanger 7 will be referred to as a “return header pipe 42”.

The sub-header 44 of the supply header pipe 41 and the sub-header 44 of the return header pipe 42 are connected to each other via a plurality of heat transfer pipes 50.

### Heat Transfer Pipe

The plurality of heat transfer pipes 50 are provided in each of the casings 11. The heat transfer pipe 50 communicates with the heat exchanger 7. The second refrigerant R2 of the heat exchanger 7 flows inside the heat transfer pipe 50. The heat transfer pipe 50 penetrates the casing 11 in the horizontal direction. The plurality of heat transfer pipes 50 extend parallel to each other and are disposed at equal intervals.

The plurality of heat transfer pipes 50 are provided at the same position in the up-down direction. The flow of the second refrigerant R2 in each heat transfer pipe 50 is a laminar flow from the supply header pipe 41 to the return header pipe 42. The heat transfer pipe 50 exchanges heat between the second refrigerant R2 and the first refrigerant R1, to cool the first refrigerant R1.

The heat transfer pipe 50 is disposed on a downstream side with respect to the heating element 3 in the flow direction of the first refrigerant R1 in the casing 11.

In addition, as shown in FIG. 4, the heat transfer pipe 50 is formed in a quadrangular tubular shape. A plurality of fins 51 are provided on an inner peripheral surface of the heat transfer pipe 50. The fins 51 are provided at corner portions of the inner peripheral surface of the heat transfer pipe 50. The heat transfer pipe 50 is a so-called extrusion pipe manufactured by extrusion.

### Circulation of First Refrigerant

Subsequently, the circulation of the first refrigerant R1 in the immersion-cooling device 10 will be described.

First, the first refrigerant R1 in the casing 11 flows into the circulation pipe 31 from one end 31a of the circulation pipe 31. The first refrigerant R1 is pumped by the pump 32 from one end 31a to the other end 31b of the circulation pipe 31. Then, the first refrigerant R1 is jetted as the jet flow from the other end 31b of the circulation pipe 31. The jet flow of the first refrigerant R1 is supplied to the heat sink mechanism 20.

The heat of the heating element 3 is transmitted to the first refrigerant R1 via the heat sink mechanism 20. In this manner, the heating element 3 is cooled. Further, the first refrigerant R1 is supplied to collide with the heat sink mechanism 20. Therefore, the heating element 3 is subjected to so-called impingement cooling.

Thereafter, the first refrigerant R1 passes through the heat sink fin 24 of the heat sink mechanism 20 and flows radially along an upper surface of the board 2. In a case where the first refrigerant R1 reaches an outer edge of the board 2, the first refrigerant R1 goes around a lower side of the board 2. Then, the first refrigerant R1 flows along a lower surface of the board 2. In this case, the first refrigerant R1 passes through the plurality of heat transfer pipes 50. The first refrigerant R1 is cooled by exchanging heat with the second refrigerant R2 in a process of passing through the plurality of heat transfer pipes 50. The first refrigerant R1 cooled by the heat transfer pipe 50 flows into one end 31a of the circulation pipe 31. The first refrigerant R1, which has flowed into one end 31a of the circulation pipe 31, is pumped again by the pump 32. In this manner, the first refrigerant R1 circulates in the immersion-cooling device 10.

### Operations and Effects

With the immersion-cooling device 10 according to the present embodiment, the following operations and effects are exhibited.

In the present embodiment, the immersion-cooling device 10 includes the casing 11 configured to stores the first refrigerant R1 and in which the board 2 is disposed to extend in the horizontal direction, the jet flow supply unit 30 configured to supply the jet flow of the first refrigerant R1 to the heating element 3, and the heat transfer pipe 50 penetrating the casing 11 and configured to cool the first refrigerant R1 by exchanging heat between the second refrigerant R2 flowing through the inner portion of the heat transfer pipe 50 and the first refrigerant R1.

As a result, the immersion-cooling device 10 can perform impingement cooling on the heating element 3 by blowing the jet flow of the first refrigerant R1 to the heating element 3. The first refrigerant R1 blown to the heating element 3 is cooled by the heat transfer pipe 50 and then used again for cooling the heating element 3. As described above, according to the present embodiment, a large-scale cycle for circulating the first refrigerant R1 is not required. Therefore, it is possible to achieve reduction in size as a whole of the equipment.

Further, since each of the casings 11 need only have a size that can accommodate one board 2, it is easy to freely use the space above the casing 11. As a result, as in the present embodiment, the casing 11 can be installed in a horizontal posture in each stage of the existing rack 8 for air cooling to extend in the horizontal direction. In addition, in the present embodiment, the casing 11 is disposed in a horizontal posture, but the casing 11 can also be disposed regardless of whether the casing 11 is in a vertical posture or a horizontal posture. In addition, by designing the casing 11 to be small enough to accommodate one board 2, the immersion-cooling device 10 can be made portable. As a result, it is easy to transport the immersion-cooling device 10 to the equipment that performs other high-speed calculation. Since an amount of the first refrigerant R1 is sufficient to fill the inside of the casing 11, it is also possible to reduce a use amount of the first refrigerant R1, which is expensive because of having insulating properties.

In addition, the immersion-cooling device 10 can cool the first refrigerant R1 stored in the casing 11 in the casing 11 by the heat transfer pipe 50. As a result, it is not required to separately provide the heat exchanger outside in order to cool the first refrigerant R1, and the number of heat exchangers can be reduced as whole equipment. Further, the circulation of the first refrigerant R1 can be completed in the immersion-cooling device 10.

As described above, since the circulation of the first refrigerant R1 can be completed in the immersion-cooling device 10 while reducing the use amount of the first refrigerant R1, the manageability of the first refrigerant R1 can also be improved.

In the present embodiment, the jet flow supply unit 30 includes the circulation pipe 31 provided outside the casing 11, having both ends communicating with the inside of the casing 11, and configured to allow the first refrigerant R1 to flow, and the pump 32 provided in the circulation pipe 31 and configured to allow the first refrigerant R1 to flow from one end 31a to the other end 31b of the circulation pipe 31. The other end 31b of the circulation pipe 31 is disposed at a position facing the heating element 3.

As a result, in the casing 11, the flow direction of the first refrigerant R1 is set by the installation locations of one end 31a and the other end 31b of the circulation pipe 31. Therefore, since the flow channel of the first refrigerant R1 in the casing 11 can be set to any value, the cooling efficiency of the immersion-cooling device 10 can be improved.

Further, the strength of the jet flow can be controlled in accordance with an amount of heat generated by the heating element 3 by adjusting a pressure of the pump 32. As a result, the heating element 3 can be cooled with the minimum jet flow corresponding to an amount of heat to be removed required for the heating element 3. Therefore, the cooling efficiency of the immersion-cooling device 10 can be improved.

In the present embodiment, in the casing 11, the heat transfer pipe 50 is disposed on the downstream side with respect to the heating element 3 in the flow direction of the first refrigerant R1.

As a result, the second refrigerant R2 flowing inside the heat transfer pipe 50 can exchange heat with the first refrigerant R1 after cooling the heating element 3. Therefore, the cooling efficiency of the immersion-cooling device 10 can be further improved.

In the present embodiment, the fins 51 are provided on the inner peripheral surface of the heat transfer pipe 50.

As a result, the surface area of the inner peripheral surface of the heat transfer pipe 50 in contact with the second refrigerant R2 is increased. Therefore, the heat transfer pipe 50 can improve the efficiency of exchange of heat between the second refrigerant R2 and the first refrigerant R1.

### First Modification Example of First Embodiment

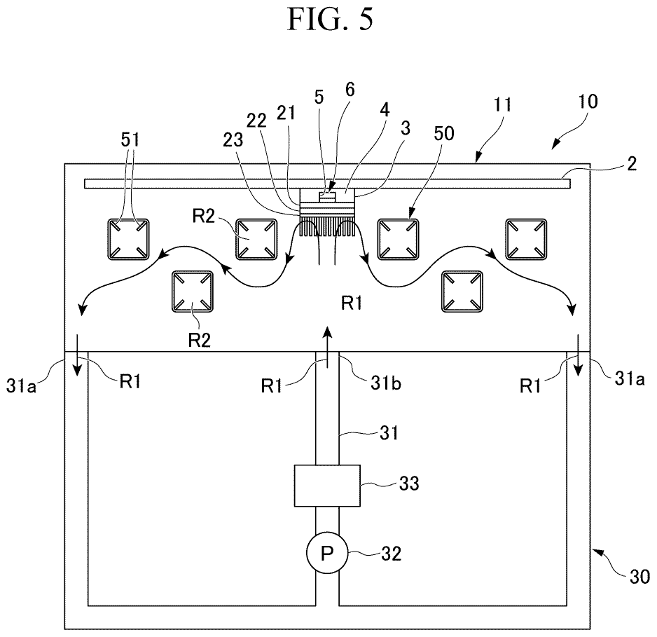

Subsequently, a first modification example of the first embodiment will be described with reference to FIG. 5.

As shown in FIG. 5, in the present modification example, the heating element 3 and the heat transfer pipe 50 are disposed on the same side (for example, the lower side of the board 2) of the board 2. The other end 31b of the circulation pipe 31 of the jet flow supply unit 30, through which the jet flow of the first refrigerant R1 is supplied, is provided directly below the heating element 3. In addition, one end 31a of the circulation pipe 31 is provided at a position close to a side wall of the casing 11. In the present modification example, one end 31a of the circulation pipe 31 is bifurcated. Both of one end 31a and the other end 31b of the circulation pipe 31 are provided on the lower surface of the casing 11.

Further, the plurality of heat transfer pipes 50 are disposed such that the positions thereof in the up-down direction are different from each other.

The jet flow of the first refrigerant R1 is supplied to the heating element 3 from below. The first refrigerant R1 flows along the lower surface of the board 2 after cooling the heating element 3. In this case, the first refrigerant R1 passes through the heat transfer pipe 50, and is cooled by exchanging heat with the second refrigerant R2 in the heat transfer pipe 50 in a process of passing through the heat transfer pipe 50. Thereafter, the first refrigerant R1 is returned to the circulation pipe 31, is pumped again by the pump 32, and is blown to the heating element 3.

In the present modification example, the plurality of heat transfer pipes 50 are disposed such that the positions thereof in the up-down direction are different from each other.

As a result, the first refrigerant R1 passes through the plurality of heat transfer pipes 50 while meandering. Therefore, the first refrigerant R1 can efficiently perform heat exchange with the second refrigerant R2. Therefore, with the immersion-cooling device 10 according to the present modification example, the cooling efficiency can be further improved.

### Second Modification Example of First Embodiment

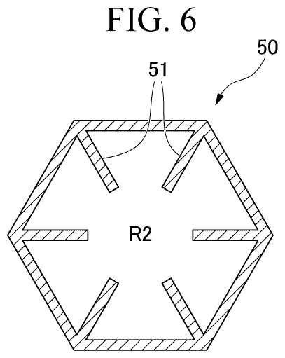

Subsequently, a second modification example of the first embodiment will be described with reference to FIG. 6.

As shown in FIG. 6, in the present modification example, the heat transfer pipe 50 is formed in a hexagonal tubular shape.

As a result, a larger amount of the second refrigerant R2 can flow in the heat transfer pipe 50. Therefore, with the immersion-cooling device 10 according to the present modification example, the cooling efficiency can be further improved.

Even in a case where the heat transfer pipe 50 is formed in a pentagonal or heptagonal or more polygonal tubular shape, the same operations and effects as the above-described operations and effects can be exhibited.

### Third Modification Example of First Embodiment

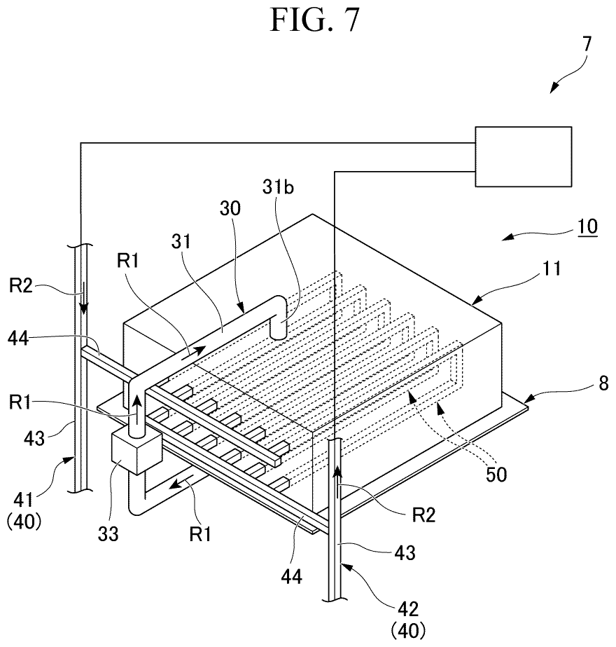

Subsequently, a third modification example of the first embodiment will be described with reference to FIG. 7.

As shown in FIG. 7, in the present modification example, the supply header pipe 41 and the return header pipe 42 are provided on the same side of the casing 11. The heat transfer pipe 50 is bent to be folded back on a side opposite to the header pipe 40 in the casing 11.

### Fourth Modification Example of First Embodiment

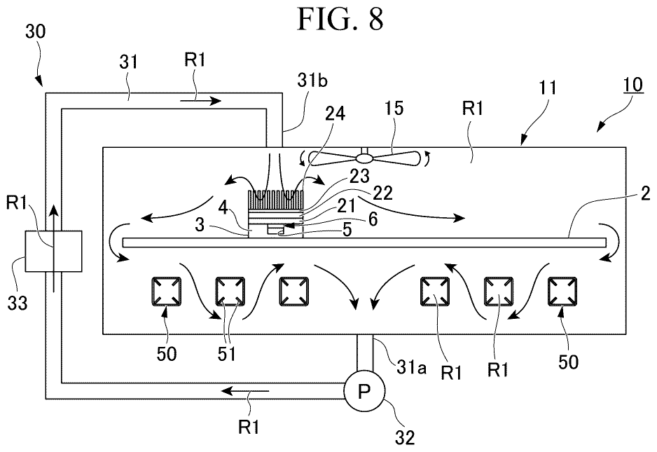

Subsequently, a fourth modification example of the first embodiment will be described with reference to FIG. 8.

As shown in FIG. 8, in the present modification example, the immersion-cooling device 10 further includes an auxiliary propeller 15. The auxiliary propeller 15 is provided in the casing 11. The auxiliary propeller 15 stirs the first refrigerant R1 flowing inside the casing 11. The stirring speed of the auxiliary propeller 15 is smaller than The jetting speed of the jet flow supply unit 30.

According to the present modification example, the immersion-cooling device 10 can allow the first refrigerant R1 to uniformly flow in the casing 11 via the auxiliary propeller 15. As a result, the immersion-cooling device 10 can efficiently cool, for example, elements other than the heating element 3 of the board 2. Therefore, with the immersion-cooling device 10 according to the present modification example, the cooling efficiency can be further improved.

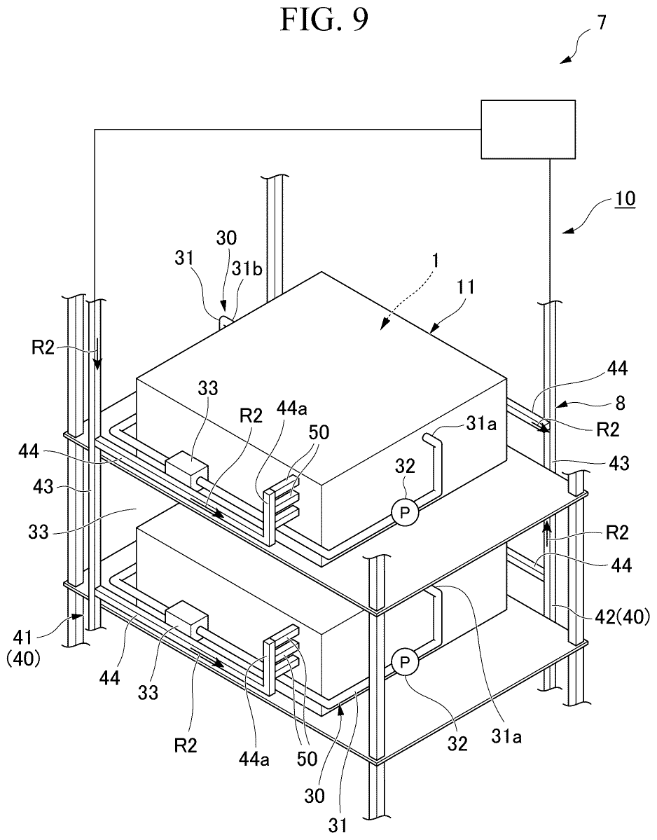

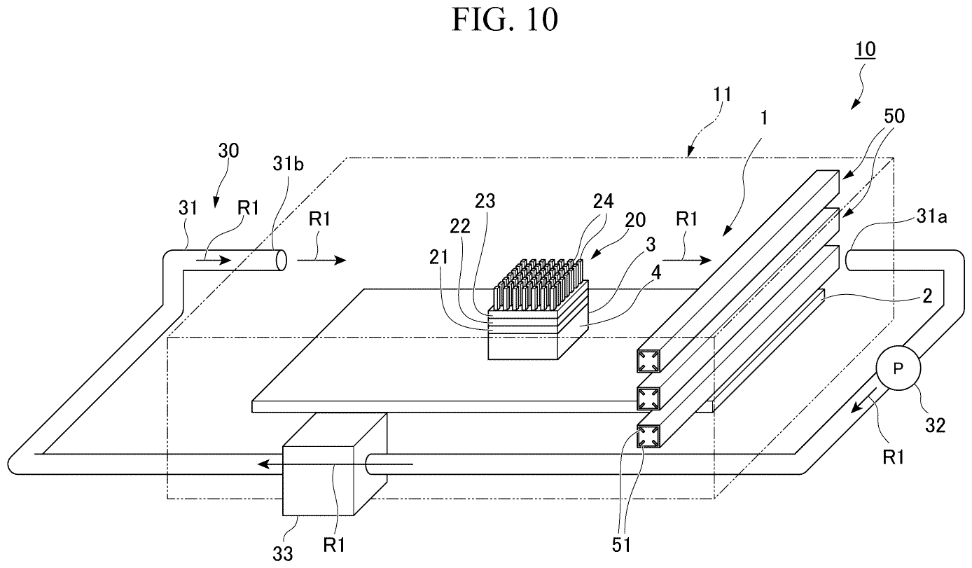

### Fifth Modification Example of First Embodiment Subsequently, a fifth modification example of the first embodiment will be described with reference to FIGS. 9 and 10.

As shown in FIGS. 9 and 10, in the present modification example, the circulation pipe 31 is provided along a side surface of the casing 11. The circulation pipe 31 is disposed to surround the casing 11 from the side. One end 31a and the other end 31b of the circulation pipe 31 are respectively provided on a pair of facing side surfaces of the casing 11. One end 31a and the other end 31b of the circulation pipe 31 are provided at positions overlapping the heat sink mechanism 20 in the horizontal direction.

The circulation pipe 31, the pump 32, and the filter 33 are provided at positions overlapping the casing 11 in the horizontal direction, not above or below the casing 11.

The sub-header 44 of the header pipe 40 is formed in an L-shape. An end portion 44a of the sub-header 44 on a side opposite to the main pipe 43 extends upward. The plurality of heat transfer pipes 50 are provided at the end portion 44a of the sub-header 44 that extends upward.

The heat transfer pipe 50 is provided on the same side as the heating element 3 in the up-down direction with the board 2 interposed therebetween, in the casing 11. The plurality of heat transfer pipes 50 are provided along a side surface of the circulation pipe 31 of the casing 11 on the one end 31a side. That is, the plurality of heat transfer pipes 50 are provided on the downstream side in the casing 11. The plurality of heat transfer pipes 50 are disposed at equal intervals in the up-down direction.

The jet flow of the first refrigerant R1 is directly supplied to the heat sink mechanism 20 in the horizontal direction. The first refrigerant R1 exchanges heat with the heating element 3 via the heat sink mechanism 20, to cool the heating element 3. The first refrigerant R1 flows along the upper surface of the board 2 after cooling the heating element 3. Then, the first refrigerant R1 passes through the heat transfer pipe 50, and is cooled by exchanging heat with the second refrigerant R2 in the heat transfer pipe 50 in a process of passing through the heat transfer pipe 50. Then, the first refrigerant R1 is returned to the circulation pipe 31, is pumped again by the pump 32, and is blown to the heat sink mechanism 20.

In the present modification example, the circulation pipe 31, the pump 32, and the filter 33 are provided at positions overlapping the casing 11 in the horizontal direction.

According to the present modification example, the immersion-cooling device 10 can be reduced in size in the up-down direction. As a result, for example, in a case where the immersion-cooling devices 10 are disposed in multiple stages in the up-down direction by the rack 8 or the like, a large number of the immersion-cooling devices 10 can be disposed in a small space.

In the present modification example, one end 31a and the other end 31b of the circulation pipe 31 are provided at positions overlapping the heat sink mechanism 20 in the horizontal direction.

According to the present modification example, the immersion-cooling device 10 can allow the first refrigerant R1 to smoothly flow in the casing 11. As a result, the immersion-cooling device 10 can reduce a pressure loss of the first refrigerant R1 in the casing 11. Therefore, the cooling efficiency of the immersion-cooling device 10 can be improved.

### Sixth Modification Example of First Embodiment

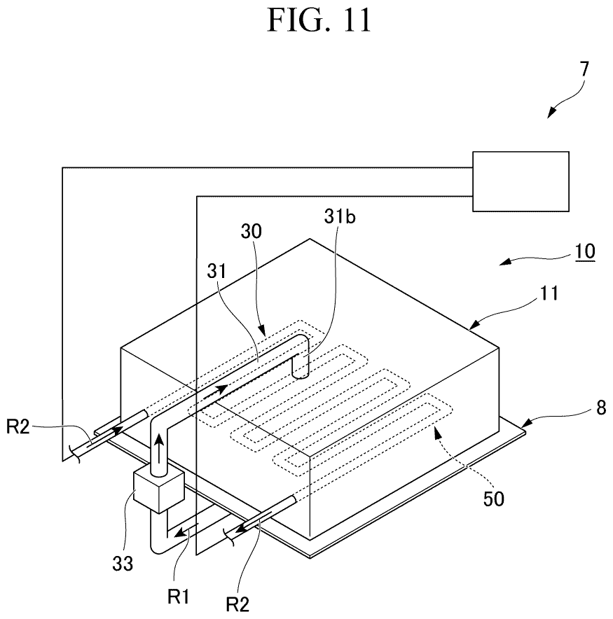

Subsequently, a sixth modification example of the first embodiment will be described with reference to FIG. 11.

As shown in FIG. 11, in the present modification example, each immersion-cooling device 10 is provided with one heat transfer pipe 50. The heat transfer pipe 50 extends in the horizontal direction in the casing 11. The heat transfer pipe 50 is provided in the casing 11 in a wave shape to be folded back a plurality of times between the pair of facing side walls. Both ends of the heat transfer pipe 50 protrude from the same side wall of the casing 11 to the outside of the casing 11. Each of both ends of the heat transfer pipe 50 are directly connected to the heat exchanger 7.

Both ends of the heat transfer pipe 50 may communicate with the heat exchanger 7 via both of the supply header pipe 41 and the return header pipe 42.

In the first embodiment and each modification example described above, the jet flow supply unit 30 includes one circulation pipe 31, and one end 31a of the circulation pipe 31, which is an inflow port of the first refrigerant R1, and the other end 31b of the circulation pipe 31, which is an outflow port of the second refrigerant R2, are each provided one by one, but the present invention is not limited to this. For example, a plurality of circulation pipes 31 may be provided, and each of the circulation pipes 31 may have one end 31a as the inflow port and the other end 31b as the outflow port. In addition, for example, both ends of one circulation pipe 31 may be branched into a plurality of pieces, and the one circulation pipe 31 may have a plurality of pieces of one end 31a as the inflow ports and a plurality of pieces of the other end 31b as the outflow ports.

In the first embodiment and each modification example described above, the filter 33 is provided in the circulation pipe 31, but the present invention is not limited to this. The filter 33 need not be provided in the circulation pipe 31.

### Second Embodiment

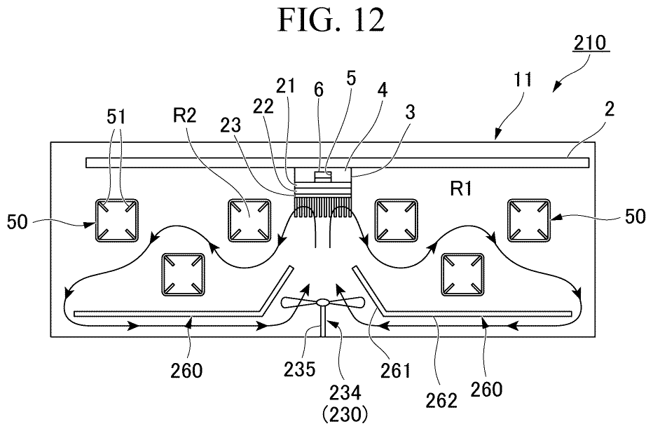

Hereinafter, an immersion-cooling device 210 according to a second embodiment of the present disclosure will be described with reference to FIG. 12. For the same configuration as the configuration of the first embodiment, the same names and the same reference numerals are used, and a description thereof will be omitted as appropriate.

As shown in FIG. 12, in the present embodiment, the jet flow supply unit 230 is a propeller 234 disposed at a position facing the heating element 3 in the casing 11. The propeller 234 is installed above the board 2. A rotating shaft 235 of the propeller 234 extends toward the heating element 3. In addition, in the present embodiment, the heating element 3 and the heat transfer pipe 50 are disposed on the same side (for example, the lower side of the board 2) of the board 2.

Further, the immersion-cooling device 210 is provided with a guide 260 that determines the flow of the first refrigerant R1 in the casing 11. The guide 260 is provided on a side wall side of the casing 11 with respect to the heating element 3 and the propeller 234. The guide 260 includes an inclined guide 261 and a horizontal guide 262. The inclined guide 261 is provided below the heating element 3. The inclined guide 261 extends in the horizontal direction while being inclined downward. The horizontal guide 262 extends from a lower end of the inclined guide 261 in a direction spaced away from the heating element 3 in the horizontal direction.

The propeller 234 generates the jet flow of the first refrigerant R1 toward the heating element 3 from below. The first refrigerant R1 is guided by an upper surface of the guide 260 after cooling the heating element 3, to flow along the lower surface of the board 2. In this case, the first refrigerant R1 passes through the heat transfer pipe 50, and is cooled by exchanging heat with the second refrigerant R2 in the heat transfer pipe 50 in a process of passing through the heat transfer pipe 50. Thereafter, the first refrigerant R1 flows along the lower surface of the guide 260, is returned to the propeller 234, and is blown to the heating element 3 again by the propeller 234.

In the present embodiment, the jet flow supply unit 230 is the propeller 234 that is disposed at a position facing the heating element 3 in the casing 11 and that has the rotating shaft 235 extending toward the heating element 3.

As a result, an entire jet flow supply unit 230 is disposed in the casing 11. Therefore, the movement of the immersion-cooling device 210 is further facilitated.

In the first embodiment and the second embodiment described above, a case has been described in which the heat transfer pipe 50 is formed in a quadrangular tubular shape or a polygonal tubular shape of a pentagonal or higher polygonal shape, but the present invention is not limited to this. The heat transfer pipe 50 may be formed in, for example, a triangular tubular shape or a cylindrical shape.

In addition, the above-described modification examples of the first embodiment may be combined with each other as appropriate, and the modification examples of the first embodiment and the second embodiment may be combined with each other as appropriate.

### Third Embodiment

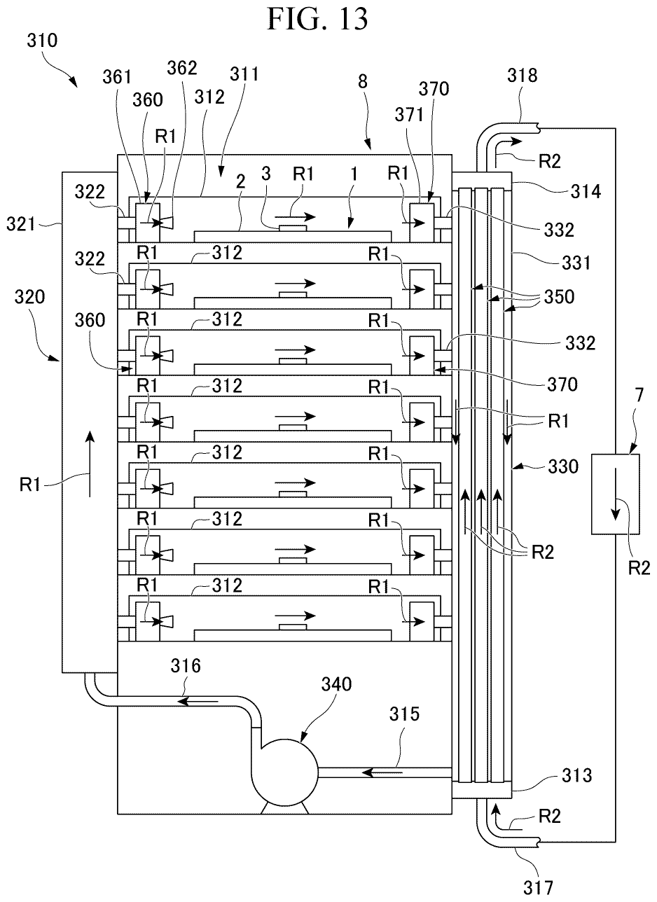

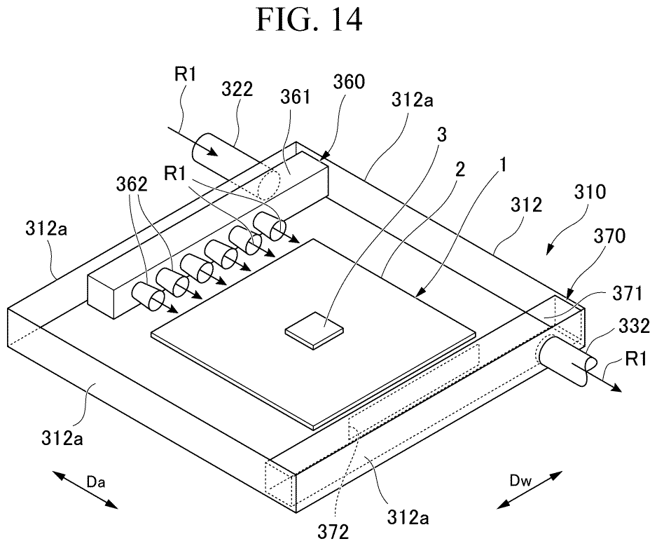

Hereinafter, an immersion-cooling device 310 according to a third embodiment of the present disclosure will be described with reference to FIGS. 13 and 14. For the same configuration as the configuration of the first embodiment, the same names and the same reference numerals are used, and a description thereof will be omitted as appropriate.

As shown in FIGS. 13 and 14, the immersion-cooling device 310 according to the present embodiment cools the heating element 3 provided on the board 2. As in the first embodiment and the second embodiment, the immersion-cooling device 310 includes a casing group 311, a supply-side header 320, a discharge-side header 330, a refrigerant pumping unit 340, a heat transfer pipe 350, an upper second header 314, a lower second header 313, a refrigerant supply unit 360, a refrigerant discharge unit 370, a first connection pipe 315, a second connection pipe 316, a third connection pipe 317, and a fourth connection pipe 318.

### Casing Group

The casing group 311 is an assembly configured by arranging the casings 312 in the up-down direction. The casing 312 has a cubic box shape extending in the horizontal direction. The casing 312 is provided in each stage of the rack 8. In the present embodiment, seven casings 312 are disposed in the up-down direction.

The casing 312 stores the first refrigerant R1. In the present embodiment, the casing 312 is filled with the first refrigerant R1. That is, an entire storage space in the casing 312 is filled with the first refrigerant R1.

The board 2 is disposed inside the casing 312 to extend in the horizontal direction. The heating element 3 is provided on a surface of the board 2.

In addition, the supply-side header 320 is provided on one side of the casing group 311 in the horizontal direction, and the discharge-side header 330 is provided on the other side of the casing group 311 in the horizontal direction. That is, the supply-side header 320 and the discharge-side header 330 are provided to face each other in the horizontal direction, with the casing group 311 interposed therebetween.

Hereinafter, a facing direction Da between the supply-side header 320 and the discharge-side header 330 will be simply referred to as a “facing direction Da”, and a horizontal direction orthogonal to the facing direction Da will be referred to as a “width direction Dw”.

### Supply-Side Header)

The supply-side header 320 extends in the up-down direction to be adjacent to the casings 312. The supply-side header 320 can introduce the first refrigerant R1 into each of the plurality of casings 312. The supply-side header 320 includes a supply-side header body 321 and a supply-side branch pipe 322.

The supply-side header body 321 is formed in a tubular shape extending in the up-down direction. Both end portions of the supply-side header body 321 in an extension direction are closed. Inside the supply-side header body 321, the first refrigerant R1 flows in the up-down direction.

A plurality of the supply-side branch pipes 322 are provided in the supply-side header body 321. The plurality of supply-side branch pipes 322 are disposed at equal intervals in the up-down direction along the casing group 311. Each of the casings 312 is provided with one supply-side branch pipe 322. The supply-side branch pipe 322 is connected to a side wall 312a of the casing 312 on a side of the supply-side header 320. The supply-side branch pipe 322 penetrates the side wall 312a of the casing 312. The supply-side branch pipe 322 is provided at one end portion of the side wall 312a of the casing 312 in the width direction Dw.

### Discharge-Side Header

The discharge-side header 330 extends in the up-down direction to be adjacent to the casings 312. The discharge-side header 330 receives introduction of the first refrigerant R1 from each of the plurality of casings 312. The discharge-side header 330 includes a discharge-side header body 331 and a discharge-side branch pipe 332.

The discharge-side header body 331 is formed in a tubular shape extending in the up-down direction. Both end portions of the discharge-side header body 331 in an extension direction are closed. Inside the discharge-side header body 331, the first refrigerant R1 flows in the up-down direction.

A plurality of the discharge-side branch pipes 332 are provided in the discharge-side header body 331. The plurality of discharge-side branch pipes 332 are disposed at equal intervals in the up-down direction along the casing group 311. Each of the casings 312 is provided with one discharge-side branch pipe 332. The discharge-side branch pipe 332 is connected to a side wall 312a of the casing 312 on a side of the discharge-side header 330. The discharge-side branch pipe 332 penetrates the side wall 312a of the casing 312. The discharge-side branch pipe 332 is provided at one end portion of the side wall 312a of the casing 312 in the width direction Dw. The discharge-side branch pipe 332 is provided at a position overlapping the supply-side branch pipe 322 in the facing direction Da.

### Refrigerant Pumping Unit

The refrigerant pumping unit 340 is provided below the casing group 311. The refrigerant pumping unit 340 is connected to a lower portion of the discharge-side header 330 by the first connection pipe 315, and is connected to a lower portion of the supply-side header 320 by the second connection pipe 316. The first connection pipe 315 allows the discharge-side header 330 and the refrigerant pumping unit 340 to communicate with each other, and the second connection pipe 316 allows the supply-side header 320 and the refrigerant pumping unit 340 to communicate with each other. The refrigerant pumping unit 340 pumps the first refrigerant R1 from the lower portion of the discharge-side header 330 to the lower portion of the supply-side header 320. The refrigerant pumping unit 340 according to the present embodiment is a pump.

### Heat Transfer Pipe

The heat transfer pipe 350 is a pipe extending inside at least one of the discharge-side header 330 and the supply-side header 320. In the present embodiment, the heat transfer pipe 350 is provided to extend in the up-down direction inside the discharge-side header 330. A plurality of the heat transfer pipes 350 are provided in the discharge-side header 330 at intervals in the horizontal direction. Inside the heat transfer pipe 350, the second refrigerant R2 flows from below to above. The heat transfer pipe 350 cools the first refrigerant R1 by exchanging heat between the second refrigerant R2 flowing through the inner portion of the heat transfer pipe 350 and the first refrigerant R1 flowing around the heat transfer pipe 350. In the present embodiment, the heat transfer pipe 350 cools the first refrigerant R1 in the discharge-side header 330 by exchanging heat between the second refrigerant R2 and the first refrigerant R1 in the discharge-side header 330.

In the present embodiment, the heat transfer pipe 350 is provided in the discharge-side header body 331 and penetrates both end walls of the discharge-side header body 331 in the extension direction.

### Lower Second Header

The lower second header 313 is provided at an upper end portion of the discharge-side header 330. The lower second header 313 is provided to cover an end wall of a lower end of the discharge-side header 330 from below. The lower second header 313 communicates with a lower end of the heat transfer pipe 350. The second refrigerant R2, which is supplied to the heat transfer pipe 350, is supplied into the lower second header 313. The lower second header 313 is connected to the external heat exchanger 7 via the third connection pipe 317. The third connection pipe 317 allows the lower second header 313 and the heat exchanger 7 to communicate with each other.

### Upper Second Header

The upper second header 314 is provided at an upper end portion of the discharge-side header 330. The upper second header 314 is provided to cover an end wall of an upper end of the discharge-side header 330 from above. The upper second header 314 communicates with an upper end of the heat transfer pipe 350. The second refrigerant R2, which has passed through the heat transfer pipe 350, is supplied into the upper second header 314. The upper second header 314 is connected to the external heat exchanger 7 via the fourth connection pipe 318. The fourth connection pipe 318 allows the upper second header 314 and the heat exchanger 7 to communicate with each other.

### Refrigerant Supply Unit

The refrigerant supply unit 360 is provided in each of the casings 312. The refrigerant supply unit 360 is provided on a side of the supply-side header 320 in the casing 312. The refrigerant supply unit 360 includes a supply-side manifold 361 and nozzles 362.

The supply-side manifold 361 is a tubular member extending in the width direction Dw along the side wall 312a of the casing 312 on a side of the supply-side header 320. The supply-side manifold 361 communicates with the supply-side branch pipe 322 at one end portion in the width direction Dw. The supply-side manifold 361 guides the first refrigerant R1, which is supplied from the supply-side header 320, into the casing 312 in the width direction Dw.

A plurality of the nozzles 362 are arranged in the supply-side manifold 361 in parallel in the width direction Dw. In the present embodiment, six nozzles 362 are provided in the width direction Dw. The nozzle 362 is a cylindrical member that communicates with the supply-side manifold 361 and that extends in the facing direction Da. The nozzle 362 is open in the facing direction Da toward the inside of the casing 312. The nozzle 362 can jet the first refrigerant R1 in the supply-side manifold 361 to a side of the discharge-side header 330. The nozzle 362 is gradually increased in diameter from the supply-side manifold 361 to a side of the discharge-side header 330 in the facing direction Da.

### Refrigerant Discharge Unit

The refrigerant discharge unit 370 is provided in each of the casings 312. The refrigerant discharge unit 370 is provided on a side of the discharge-side header 330 in the casing 312. The refrigerant discharge unit 370 includes a discharge-side manifold 371.

The discharge-side manifold 371 is a tubular member extending in the width direction Dw along a side wall 312a of the casing 312 on a side of the discharge-side header 330. An introduction hole 372 that penetrates the side wall 312a is provided in a side wall of the discharge-side manifold 371 on a side of the supply-side header 320.

The first refrigerant R1 in the casing 312 is introduced into the discharge-side manifold 371 through the introduction hole 372. The discharge-side manifold 371 communicates with the discharge-side branch pipe 332 at one end portion in the width direction Dw. The discharge-side manifold 371 guides the first refrigerant R1, which is discharged from the inside of the casing 312, to the discharge-side header 330.

### Circulation of First Refrigerant

Subsequently, the circulation of the first refrigerant R1 in the immersion-cooling device 310 will be described.

First, in a case where the refrigerant pumping unit 340 is operated, the first refrigerant R1 is supplied from the supply-side header 320 to the casings 312. In this case, the first refrigerant R1 is jetted into the casing 312 by a plurality of nozzles 362.

The first refrigerant R1 flows through the casing 312 in the facing direction Da as the jet flow. The first refrigerant R1 in the casing 312 passes through the heating element 3 and exchanges heat with the heating element 3. As a result, the heating element 3 is cooled. On the other hand, the first refrigerant R1 is heated by receiving heat of the heating element 3. Thereafter, the first refrigerant R1 is introduced from each of the casings 312 to the discharge-side header 330. The first refrigerant R1 flows from the upper side to the lower side in the discharge-side header 330 due to the pressure of the refrigerant pumping unit 340 and the dead weight.

Meanwhile, in the heat transfer pipe 350, the second refrigerant R2 flows from below to above. That is, the first refrigerant R1 and the second refrigerant R2 flow in directions opposite to each other in the up-down direction. The first refrigerant R1 exchanges heat with the second refrigerant R2 in a process of flowing inside the discharge-side header 330. As a result, the first refrigerant R1 is cooled, and the second refrigerant R2 is heated. The second refrigerant R2 is sent to the heat exchanger 7 provided outside, after exchanging heat with the first refrigerant R1. The second refrigerant R2 is cooled by the heat exchanger 7, and is supplied to each heat transfer pipe 350 again.

In a case where the first refrigerant R1 is cooled by exchanging heat with the second refrigerant R2, the first refrigerant R1 is pumped again to the supply-side header 320 by the refrigerant pumping unit 340. Then, the first refrigerant R1 is supplied to the casings 312 again as described above. In this manner, the first refrigerant R1 circulates in the immersion-cooling device 310.

### Operations and Effects

With the immersion-cooling device 310 according to the present embodiment, the following operations and effects are exhibited.

In the present embodiment, the immersion-cooling device 310 includes the casing group 311 including the plurality of casings 312, which form a box shape extending in the horizontal direction and in which the board 2 is disposed to extend in the horizontal direction, the casing group 311 being configured by arranging the plurality of casings 312 in an up-down direction, the supply-side header 320 extending in the up-down direction to be adjacent to the casings 312 and configured to introduce the first refrigerant R1 into each of the plurality of casings 312, the discharge-side header 330 extending in the up-down direction to be adjacent to the casings 312 and configured to receive introduction of the first refrigerant R1 from each of the plurality of casings 312, the refrigerant pumping unit 340 configured to pump the first refrigerant R1 from the discharge-side header 330 to the supply-side header 320, and the heat transfer pipe 350 extending inside at least one of the discharge-side header 330 and the supply-side header 320 and configured to cool the first refrigerant R1 by exchanging heat between the second refrigerant R2 flowing through the inner portion of the heat transfer pipe 350 and the first refrigerant R1.

As a result, the heat transfer pipe 350 can be provided along the casings 312, for the plurality of casings 312 arranged in the up-down direction. Therefore, it is possible to suppress the expansion of the immersion-cooling device 310 in the horizontal direction. Therefore, the immersion-cooling device 310 can be reduced in size in the horizontal direction. In addition, since the flow channel of the first refrigerant R1 is compactly arranged in the horizontal direction, the first refrigerant R1 is easily managed. That is, it is possible to improve the manageability of the first refrigerant R1.

In the present embodiment, the heat transfer pipe 350 extends in the up-down direction.

As a result, the arrangement direction of the casing 312 and the extension direction of the heat transfer pipe 350 coincides with each other. Therefore, the disposition efficiency of the configuration of the immersion-cooling device 310, such as the casing 312 or the heat transfer pipe 350, is improved. Further, since the heat transfer pipe 350 can be provided to extend in the up-down direction inside the supply-side header 320 and the discharge-side header 330 extending in the up-down direction, a distance over which the heat exchange is performed between the first refrigerant R1 and the second refrigerant R2 can be increased. Therefore, the immersion-cooling device 310 can efficiently cool the first refrigerant R1. Therefore, it is possible to improve the cooling efficiency of the immersion-cooling device 310.

In the present embodiment, the refrigerant pumping unit 340 pumps the first refrigerant R1 from the lower portion of the discharge-side header 330 to the supply-side header 320, the heat transfer pipe 350 is provided to extend inside the discharge-side header 330, and the second refrigerant R2 flows from below to above.

As a result, the first refrigerant R1 flows upward in the supply-side header 320, and is supplied into the casing 312. Thereafter, the first refrigerant R1 is discharged from the inside the casing 312 to the discharge-side header 330, and flows downward in the discharge-side header 330. On the other hand, the second refrigerant R2 flows upward inside the heat transfer pipe 350 provided in the discharge-side header 330. Therefore, inside the discharge-side header 330, the flow of the first refrigerant R1 and the flow of the second refrigerant R2 are in counter flow in which the flow directions are opposite to each other. Therefore, the efficiency of heat exchange between the first refrigerant R1 and the second refrigerant R2 is improved. Therefore, the immersion-cooling device 310 can further efficiently cool the first refrigerant R1. Therefore, it is possible to further improve the cooling efficiency of the immersion-cooling device 310.

In addition, since the heat transfer pipe 350 is provided inside the discharge-side header 330, the immersion-cooling device 310 can cool the first refrigerant R1 with the heat transfer pipe 350 and then guide the first refrigerant R1 to the refrigerant pumping unit 340.

In the present embodiment, the supply-side header 320 is provided on one side of the casing group 311 in the horizontal direction, the discharge-side header 330 is provided on the other side of the casing group 311 in the horizontal direction, the immersion-cooling device 310 further includes the refrigerant supply unit 360 provided in each of the casings 312, and the refrigerant supply unit 360 includes the supply-side manifold 361 configured to guide the first refrigerant R1 supplied from the supply-side header 320 in the width direction Dw that is the horizontal direction orthogonal to the facing direction Da between the supply-side header 320 and the discharge-side header 330, and the plurality of nozzles 362 arranged in the supply-side manifold 361 in parallel in the width direction Dw and configured to jet the first refrigerant R1 in the supply-side manifold 361 to a side of the discharge-side header 330.

As a result, the immersion-cooling device 310 can jet the first refrigerant R1 to the heating element 3 of the board 2. Further, since the discharge-side header 330 is present in the jetting direction of the first refrigerant R1, the first refrigerant R1, which has completed heat exchange, can be smoothly discharged. Therefore, the immersion-cooling device 310 can reduce a pressure loss of the first refrigerant R1 in the casing 312. Therefore, it is possible to further improve the cooling efficiency of the immersion-cooling device 310.

In the above-described third embodiment, a case has been described in which the seven casings 312 are disposed in the up-down direction, but the present invention is not limited to this. The number of the casings 312 can be changed as appropriate.

In the third embodiment described above, a case has been described in which the refrigerant pumping unit 340 is provided below the casing group 311, but the present invention is not limited to this. The refrigerant pumping unit 340 may be provided above the casing group 311. In this case, the refrigerant pumping unit 340 pumps the first refrigerant R1 from the upper portion of the discharge-side header 330 to the supply-side header 320.

In the third embodiment described above, the heat transfer pipe 350 is provided to extend inside the discharge-side header 330, but the present invention is not limited to this. The heat transfer pipe 350 may be provided to extend inside the supply-side header 320. In this case, the first refrigerant R1 is cooled by the heat transfer pipe 350 immediately before the first refrigerant R1 is introduced into the casing 312. Therefore, the immersion-cooling device 310 can more efficiently cool the heating element 3 in the casing 312. That is, it is possible to improve the cooling efficiency of the immersion-cooling device 310. In addition, the heat transfer pipe 350 may be provided to extend inside both of the discharge-side header 330 and the supply-side header 320.

In the third embodiment described above, a case has been described in which the heat transfer pipes 350 extend in the up-down direction along the casing group 311 and the plurality of heat transfer pipes 350 are provided at intervals in the horizontal direction, but the present invention is not limited to this. The plurality of heat transfer pipes 350 may be provided to extend in the horizontal direction at intervals in the up-down direction along the casing group 311.

In the third embodiment described above, a case has been described in which the six nozzles 362 are provided in the width direction Dw, but the present invention is not limited to this. The number of the nozzles 362 can be changed as appropriate.

### Other Embodiments

Although the embodiments of the present disclosure have been described in detail above with reference to the drawings, the specific configuration is not limited to this embodiment, and design changes and the like that do not depart from the gist of the present disclosure are also included.

### Supplementary Note

The immersion-cooling devices 10, 210, and 310 described in each embodiment are understood, for example, as follows.
(1) A first aspect relates to an immersion-cooling device 310 that cools a heating element 3 provided on a board 2, the immersion-cooling device 310 including: a casing group 311 including a plurality of casings 312, which form a box shape extending in a horizontal direction and in which the board 2 is disposed to extend in the horizontal direction, the casing group 311 being configured by arranging the plurality of casings 312 in an up-down direction; a supply-side header 320 extending in the up-down direction to be adjacent to the casings 312 and configured to introduce a first refrigerant R1 into each of the plurality of casings 312; a discharge-side header 330 extending in the up-down direction to be adjacent to the casings 312 and configured to receive introduction of the first refrigerant R1 from each of the plurality of casings 312; a refrigerant pumping unit 340 configured to pump the first refrigerant R1 from the discharge-side header 330 to the supply-side header 320; and a heat transfer pipe 350 extending inside at least one of the discharge-side header 330 and the supply-side header 320 and configured to cool the first refrigerant R1 by exchanging heat between a second refrigerant R2 flowing through an inner portion of the heat transfer pipe 350 and the first refrigerant R1.

As a result, the heat transfer pipe 350 can be provided along the casings 312, for the plurality of casings 312 arranged in the up-down direction. Therefore, it is possible to suppress the expansion of the immersion-cooling device 310 in the horizontal direction.
(2) A second aspect relates to the immersion-cooling device 310 according to the first aspect, in which the heat transfer pipe 350 may extend in the up-down direction.

As a result, the arrangement direction of the casing 312 and the extension direction of the heat transfer pipe 350 coincides with each other. Therefore, the disposition efficiency of the configuration of the immersion-cooling device 310, such as the casing 312 or the heat transfer pipe 350, is improved. Further, since the heat transfer pipe 350 can be provided to extend in the up-down direction inside the supply-side header 320 and the discharge-side header 330 extending in the up-down direction, a distance over which the heat exchange is performed between the first refrigerant R1 and the second refrigerant R2 can be increased.
(3) A third aspect relates to the immersion-cooling device 310 according to the second aspect, in which the refrigerant pumping unit 340 may pump the first refrigerant R1 from a lower portion of the discharge-side header 330 to the supply-side header 320, the heat transfer pipe 350 may be provided to extend inside the discharge-side header 330, and the second refrigerant R2 may flow from below to above.

As a result, the first refrigerant R1 flows upward in the supply-side header 320, and is supplied into the casing 312. Thereafter, the first refrigerant R1 is discharged from the inside the casing 312 to the discharge-side header 330, and flows downward in the discharge-side header 330. On the other hand, the second refrigerant R2 flows upward inside the heat transfer pipe 350 provided in the discharge-side header 330. Therefore, inside the discharge-side header 330, the flow of the first refrigerant R1 and the flow of the second refrigerant R2 are in counter flow in which the flow directions are opposite to each other. Therefore, the efficiency of heat exchange between the first refrigerant R1 and the second refrigerant R2 is improved.
(4) A fourth aspect relates to the immersion-cooling device 310 according to any one of the first to third aspects, in which the supply-side header 320 may be provided on one side of the casing group 311 in the horizontal direction, the discharge-side header 330 may be provided on the other side of the casing group 311 in the horizontal direction, the immersion-cooling device 310 may further include a refrigerant supply unit 360 provided in each of the casings 312, and the refrigerant supply unit 360 may include a supply-side manifold 361 configured to guide the first refrigerant R1 supplied from the supply-side header 320 in a width direction Dw that is a horizontal direction orthogonal to a facing direction Da between the supply-side header 320 and the discharge-side header 330, and a plurality of nozzles 362 arranged in the supply-side manifold 361 in parallel in the width direction Dw and configured to jet the first refrigerant R1 in the supply-side manifold 361 to a side of the discharge-side header 330.

As a result, the immersion-cooling device 310 can jet the first refrigerant R1 to the heating element 3 of the board 2. Further, since the discharge-side header 330 is present in the jetting direction of the first refrigerant R1, the first refrigerant R1, which has completed heat exchange, can be smoothly discharged.
(5) A fifth aspect relates to an immersion-cooling device 10, 210 that cools a heating element 3 provided on a board 2, the immersion-cooling device 10, 210 including: a casing 11 configured to store a first refrigerant R1 and in which the board 2 is disposed to extend in a horizontal direction; a jet flow supply unit 30, 230 configured to supply a jet flow of the first refrigerant R1 to the heating element 3; and a heat transfer pipe 50 penetrating the casing 11 and configured to cool the first refrigerant R1 by exchanging heat between a second refrigerant R2 flowing through an inner portion of the heat transfer pipe 50 and the first refrigerant R1.

As a result, the immersion-cooling device 10, 210 can perform impingement cooling on the heating element 3 by blowing the jet flow of the first refrigerant R1 to the heating element 3. The first refrigerant R1 blown to the heating element 3 is cooled by the heat transfer pipe 50 and then used again for cooling the heating element 3. As described above, according to the present aspect, a large-scale circulation cycle is not required to circulate the first refrigerant R1. In addition, the immersion-cooling device 10, 210 can cool the first refrigerant R1, which is stored in the casing 11, in the casing 11 via the heat transfer pipe 50.
(6) A sixth aspect relates to the immersion-cooling device 10 according to the fifth aspect, in which the jet flow supply unit 30 may include a circulation pipe 31 provided outside the casing 11, having both ends communicating with an inside of the casing 11, and configured to allow the first refrigerant R1 to flow, and a pump 32 provided in the circulation pipe 31 and configured to allow the first refrigerant R1 to flow from one end 31a to the other end 31b of the circulation pipe 31, and the other end 31b of the circulation pipe 31 may be disposed at a position facing the heating element 3.

As a result, in the casing 11, the flow direction of the first refrigerant R1 is set by the installation locations of one end 31a and the other end 31b of the circulation pipe 31.
(7) A seventh aspect relates to the immersion-cooling device 210 according to the fifth aspect, in which the jet flow supply unit 230 may be a propeller 234 disposed at a position facing the heating element 3 in the casing 11 and having a rotating shaft 235 extending toward the heating element 3.

As a result, an entire jet flow supply unit 230 is disposed in the casing 11.
(8) An eighth aspect relates to the immersion-cooling device 10, 210 according to any one of the fifth to seventh aspects, in which, in the casing 11, the heat transfer pipe 50 may be disposed on a downstream side with respect to the heating element 3 in a flow direction of the first refrigerant R1.

As a result, the second refrigerant R2 flowing inside the heat transfer pipe 50 can exchange heat with the first refrigerant R1 after cooling the heating element 3.
(9) A ninth aspect relates to the immersion-cooling device 10, 210 according to any one of the fifth to eighth aspects, in which a fin 51 may be provided on an inner peripheral surface of the heat transfer pipe 50.

As a result, the surface area of the inner peripheral surface of the heat transfer pipe 50 in contact with the second refrigerant R2 is increased.

### INDUSTRIAL APPLICABILITY

With the immersion-cooling device according to the present disclosure, it is possible to improve the manageability of the refrigerant while achieving the reduction in size.

### REFERENCE SIGNS LIST

1 Server
2 Board
3 Heating element
4 Base portion
5 Recess portion
6 Heating element body
7 Heat exchanger
8 Rack
10 Immersion-cooling device
11 Casing
15 Auxiliary propeller
20 Heat sink mechanism
21 First heat transfer plate
22 Grease
23 Second heat transfer plate
24 Heat sink fin
30 Jet flow supply unit
31 Circulation pipe
31a One end
31b Other end
32 Pump
33 Filter
40 Header pipe
41 Supply header pipe
42 Return header pipe
43 Main pipe
44 Sub-header
44a End portion
50 Heat transfer pipe
51 Fin
210 Immersion-cooling device
230 Jet flow supply unit
234 Propeller
235 Rotating shaft
260 Guide
261 Inclined guide
262 Horizontal guide
310 Immersion-cooling device
311 Casing group
312 Casing
312a Side wall
313 Lower second header
314 Upper second header
315 First connection pipe
316 Second connection pipe
317 Third connection pipe
318 Fourth connection pipe
320 Supply-side header
321 Supply-side header body
322 Supply-side branch pipe
330 Discharge-side header
331 Discharge-side header body
332 Discharge-side branch pipe
340 Refrigerant pumping unit
350 Heat transfer pipe
360 Refrigerant supply unit
361 Supply-side manifold
362 Nozzle
370 Refrigerant discharge unit
371 Discharge-side manifold
372 Introduction hole
R1 First refrigerant
R2 Second refrigerant
Da Facing direction
Dw Width direction

1. An immersion-cooling device that cools a heating element provided on a board, the immersion-cooling device comprising:
a casing group including a plurality of casings, which form a box shape extending in a horizontal direction and in which the board is disposed to extend in the horizontal direction, the casing group being configured by arranging the plurality of casings in an up-down direction;
a supply-side header extending in the up-down direction to be adjacent to the casings and configured to introduce a first refrigerant into each of the plurality of casings;
a discharge-side header extending in the up-down direction to be adjacent to the casings and configured to receive introduction of the first refrigerant from each of the plurality of casings;
a refrigerant pumping unit configured to pump the first refrigerant from the discharge-side header to the supply-side header; and
a heat transfer pipe extending inside at least one of the discharge-side header and the supply-side header and configured to cool the first refrigerant by exchanging heat between a second refrigerant flowing through an inner portion of the heat transfer pipe and the first refrigerant.

2. The immersion-cooling device according to claim 1, wherein the heat transfer pipe extends in the up-down direction.

3. The immersion-cooling device according to claim 2,
wherein the refrigerant pumping unit pumps the first refrigerant from a lower portion of the discharge-side header to the supply-side header,
the heat transfer pipe is provided to extend inside the discharge-side header, and
the second refrigerant flows from below to above.

4. The immersion-cooling device according to claim 1,
wherein the supply-side header is provided on one side of the casing group in the horizontal direction,
the discharge-side header is provided on the other side of the casing group in the horizontal direction,
the immersion-cooling device further comprises a refrigerant supply unit provided in each of the casings, and
the refrigerant supply unit includes
a supply-side manifold configured to guide the first refrigerant supplied from the supply-side header in a width direction that is a horizontal direction orthogonal to a facing direction between the supply-side header and the discharge-side header, and
a plurality of nozzles arranged in the supply-side manifold in parallel in the width direction and configured to jet the first refrigerant in the supply-side manifold to a side of the discharge-side header.

5. An immersion-cooling device that cools a heating element provided on a board, the immersion-cooling device comprising:
a casing configured to store a first refrigerant and in which the board is disposed to extend in a horizontal direction;
a jet flow supply unit configured to supply a jet flow of the first refrigerant to the heating element; and
a heat transfer pipe penetrating the casing and configured to cool the first refrigerant by exchanging heat between a second refrigerant flowing through an inner portion of the heat transfer pipe and the first refrigerant.

6. The immersion-cooling device according to claim 5,
wherein the jet flow supply unit includes
a circulation pipe provided outside the casing, having both ends communicating with an inside of the casing, and configured to allow the first refrigerant to flow, and
a pump provided in the circulation pipe and configured to allow the first refrigerant to flow from one end to the other end of the circulation pipe, and
the other end of the circulation pipe is disposed at a position facing the heating element.

7. The immersion-cooling device according to claim 5,
wherein the jet flow supply unit is a propeller disposed at a position facing the heating element in the casing and having a rotating shaft extending toward the heating element.

8. The immersion-cooling device according to claim 5,
wherein, in the casing, the heat transfer pipe is disposed on a downstream side with respect to the heating element in a flow direction of the first refrigerant.

9. The immersion-cooling device according to claim 5,
wherein a fin is provided on an inner peripheral surface of the heat transfer pipe.
